(19) United States
(12) Patent Application Publication
(10) Pub. No.: US 2010/0012186 A1
(43) Pub. Date: Jan. 21, 2010

(54) Bulb-Type Light Concentrated Solar Cell Module

(75) Inventors: Yoon-dong Park, Gyeonggi-do (KR); Kwang-soo Seol, Gyeonggi-do (KR); Deok-kee Kim, Gyeonggi-do (KR); Won-joo Kim, Gyeonggi-do (KR); Young-gu Jin, Gyeonggi-do (KR); Seung-hoon Lee, Seoul (KR); Suk-pil Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/436,832

(22) Filed: May 7, 2009

(30) Foreign Application Priority Data
Jul. 18, 2008 (KR) 2008-70163

(51) Int. Cl. H01L 31/00

(52) U.S. Cl. 136/259

(57) ABSTRACT

Provided is a bulb-type light concentrated solar cell module that includes a reflective mirror unit that is concavely formed to convergingly reflect sunlight and has a first hole on a bottom thereof; a solar cell that generates electrical energy in response to light received from the reflective mirror unit; a socket that blocks the first hole at a lower part of the reflective mirror unit and is fixed on the reflective mirror unit; and a power control unit that is electrically connected to the solar cell to generate electricity in the socket.

### REFERENCE TO PRIORITY APPLICATION

This application claims the benefit of Korean Patent Application No. 10-2008-0070163, filed on Jul. 18, 2008, the disclosure of which is incorporated herein by reference in its entirety as if set forth fully herein.

### FIELD OF THE INVENTION

The present invention relates to a bulb-type light concentrated solar cell module, and more particularly, to a bulb-type light concentrated solar cell module that may be readily replaced and which has an improved photovoltaic efficiency.

### BACKGROUND OF THE INVENTION

A solar cell module generally includes a plurality of photovoltaic cells connected in series. Photovoltaic cells are classified into thin film type photovoltaic cells that use crystalline silicon or poly silicon and concentration type photovoltaic cells that focus solar light.

The concentration type solar cell module concentrates solar light and then transmits the concentrated light to a solar cell, and thus, has an improved photovoltaic efficiency. The concentration type solar cell module is disposed in an array shape, and produces power through an additional inverter. In the case when one of the concentration type solar cell modules is not operated, the power generation efficiency of the entire solar cell system may be reduced. Also, it is not easy to replace a concentration type solar cell module that is defective.

Also, even despite the previous efforts the photovoltaic efficiency of the concentration type solar cell module remains at approximately 30% to 40%. Thus, there is a need to develop a technique that can increase the photovoltaic efficiency.

### SUMMARY OF THE INVENTION

To address the above and/or other problems, the present invention provides a bulb-type light concentrated solar cell module that may be readily replaced.

The present invention also provides a bulb-type light concentrated solar cell module that can increase power efficiency by producing electricity using a reflective film used for concentrating light.

The present invention also provides a bulb-type light concentrated solar cell module that can increase power efficiency by preventing electrons from being recombined with holes at a surface of a solar cell.

According to an aspect of the present invention, there is provided a bulb-type light concentrated solar cell module comprising: a reflective mirror unit that is concavely formed to reflect sunlight inwards and has a first hole on a bottom thereof; a solar cell that generates electrical energy in response to light received from the reflective mirror unit; a socket that blocks the first hole at a lower part of the reflective mirror unit and is fixed on the reflective mirror unit; and a power control unit that is electrically connected to the solar cell to generate electricity in the socket.

The solar cell may be disposed above the first hole for light reflected by the reflective mirror unit to be incident thereon.

The solar cell may be positioned on the first hole, and may further comprise a second reflective mirror disposed above the first hole to reflect light incident thereon from the reflective mirror unit onto the solar cell.

The reflective mirror unit may comprise: a concave substrate; and a plurality of thermoelectric cells formed on the substrate, wherein each of the thermoelectric cells comprises a p-type stack and an n-type stack, the p-type stack comprises a first electrode on the substrate, a p-type thermoelectric material film on the first electrode, and a second electrode on the p-type thermoelectric material film, and the n-type stack comprises a first electrode on the substrate, an n-type thermoelectric material film on the first electrode, and a second electrode on the n-type thermoelectric material film.

The first electrode of the p-type stack and the first electrode of the n-type stack may be respectively connected to a p-type terminal and an n-type terminal of the power control unit.

The thermoelectric cell may comprise a plurality of thermoelectrical cell connected in series, and the first electrode of the p-type stack of the first thermoelectric cell and the first electrode of the n-type stack of the last thermoelectric cell are respectively connected to a p-type terminal and an n-type terminal of the power control unit.

The p-type thermoelectric material film may be formed of at least one selected from the group consisting of (Bi,Sb)₂Te₃, Ca₃Co₄O₉, and (Bi₂Te₃)_{0.2}(Sb₂Te₃)_{0.8-y}(Sb₂Se₃)_{y} (0≦y≦0.07), and the n-type thermoelectric material film may be formed of at least one selected from the group consisting of Bi₂(Te,Se)₃, Nb-doped SrTiO₃, and CaMn_{0.98}Mo_{0.02}O₃, (Bi₂Te₃)_{0.9}(Sb₂Te₃)_{0.05}(Sb₂Se₃)_{0.05}.

The p-type thermoelectric material film and the n-type thermoelectric material film may be each a nanowire.

The bulb-type light concentrated solar cell module may further comprise a transparent cover formed on the reflective mirror unit to form a sealed space with the reflective mirror unit, and a first gas filled in the sealed space,

wherein the solar cell comprises a plurality of unit cells each having a third electrode formed towards the reflective mirror unit and a fourth electrode opposite to the third electrode, a fifth electrode formed laterally adjacent to the third electrode and separate from the third electrode,

and the first gas having an electron affinity higher than that of the third electrode, and the fifth electrode is formed of a metal having an electron affinity higher than that of the first gas.

The third electrode and the fifth electrode may be connected together to the n-type terminal of the power control unit, and the fourth electrode may be connected to the p-type terminal of the power control unit.

The first gas may be one of F₂, Cl₂, and I₂.

The fifth electrode may be formed of a metal selected from the group consisting of Pt, Pd, and TaN.

The bulb-type light concentrated solar cell module may further comprise a transparent cover formed above the reflective mirror unit to form a sealed space with the reflective mirror unit, and

The bulb-type light concentrated solar cell module may further comprise a transparent cover formed on the reflective mirror unit to form a sealed space with the reflective mirror unit, and an inert gas filled in the sealed space, wherein the solar cell may comprise a plurality of unit cells each having a third electrode formed towards the reflective mirror unit and a fourth electrode opposite to the third electrode, and a fluorine group molecule of CoF₄ or tetrafluorotetracyanoquinodimethane (F4-TCNQ) adsorbed on a surface of the third electrode, a fifth electrode formed laterally adjacent to the third electrode and separate from the third electrode, wherein the fifth electrode is formed of a metal having an electron affinity higher than that of the fluorine group molecule of CoF₄ or F4-TCNQ.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a bulb-type light concentrated solar cell module according to an embodiment of the present invention;

FIG. 2 is a perspective view of a module mounting panel in which the bulb-type light concentrated solar cell modules of FIG. 1 are detachably mounted;

FIG. 3 is a cross-sectional view of a unit cell of the solar cell of FIG. 1;

FIG. 4 is a schematic drawing for explaining the movement of electrons at a surface of the unit cell of the solar cell of FIG. 1;

FIG. 5 is a schematic drawing for explaining the operation of a solar cell according to an embodiment of the present invention;

FIG. 6 is a cross-sectional view of a modified version of the stricture of the reflective mirror unit of FIG. 1;

FIG. 7 is a block diagram showing an example of the power control unit of FIG. 1; and

FIG. 8 is a cross-sectional view of a bulb-type light concentrated solar cell module according to another embodiment of the present invention.

### DETAILED DESCRIPTION OF THE INVENTION

The present invention will now be described more fully with reference to the accompanying drawings in which exemplary embodiments of the invention are shown. In the drawings, the thicknesses of layers and regions are exaggerated for clarity. Like reference numerals in the drawings denote like elements, and thus their description will be omitted.

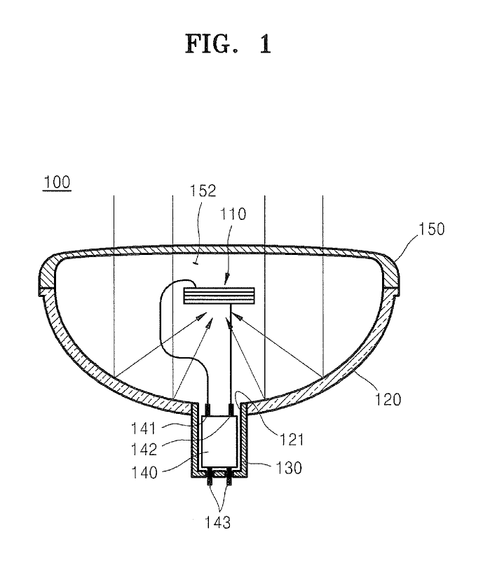

FIG. 1 is a cross-sectional view of a bulb-type light concentrated solar cell module 100 according to an embodiment of the present invention.

Referring to FIG. 1, the bulb-type light concentrated solar cell module 100 includes a solar cell 110 that generates electrical energy in response to light and a reflection mirror unit 120 which is installed below the solar cell 110 to receive and focus light to the solar cell 110. The reflection mirror unit 120 has a concave shape, and the solar cell 110 is disposed in a position where reflected light by the reflection mirror unit 120 is focused.

A first hole 121 is formed in the center of a bottom of the reflection mirror unit 120. The solar cell 110 is positioned above the first hole 121. The bulb-type light concentrated solar cell module 100 further includes a socket 130 that blocks the first hole 121 at a lower part of the reflection mirror unit 120. The socket 130 is fixedly installed on the reflection mirror unit 120. A power control unit 140 is installed in the socket 130. The power control unit 140 includes an inverter (not shown) that is connected to two electrodes of the solar cell 110 to convert a direct current to an alternate current. The power control unit 140 also includes an n-type terminal 141 through which electrons enter from the solar cell 110, a p-type terminal 142 through which holes enter from the solar cell 110, and terminals 143 that supply power to an external load or an electric condenser.

A transparent cover 150 having a convex shape is installed on the reflection mirror unit 120. The transparent cover 150 and the reflection mirror unit 120 form a sealed space 152 therebetween by combining with each other. A gas which will be described later may be filled in the sealed space 152. The transparent cover 150 may be formed of glass or plastic.

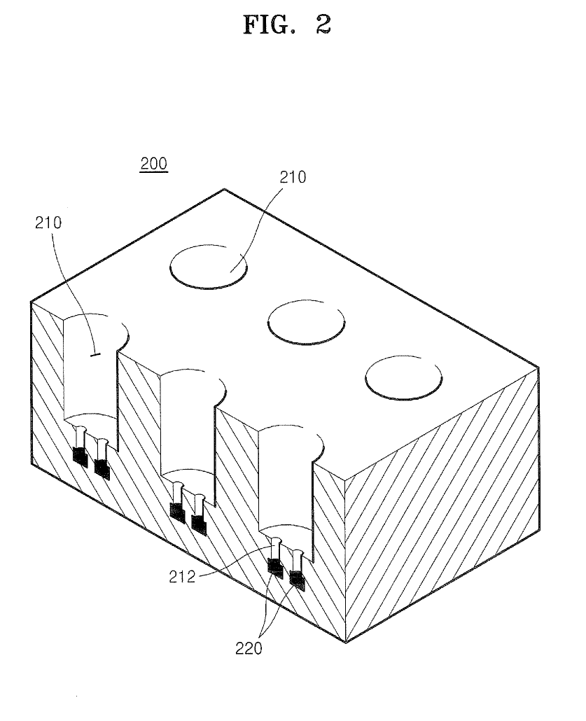

FIG. 2 is a perspective view of a module mounting panel 200 in which the bulb-type light concentrated solar cell module 100 of FIG. 1 are detachably mounted. A plurality of groves 210 are formed in the module mounting panel 200, and the groves 210 may be arranged in an array. The socket 130 of the bulb-type light concentrated solar cell module 100 of FIG. 1 may be mounted in each of the groves 210. Holes 212 into which the terminals 143 of the power control unit 140 are inserted may be formed on a lower part of each of the grooves 210. A contact point 220 is formed on an end portion each of the holes 212. Power generated by the power control units 140 are collected through the contact points 220 or may be connected to an external load (not shown) or a condenser battery (not shown).

The solar cell module according to an embodiment of the present invention is of a bulb-type, and the number of the solar cell modules 100 mounted in the groves 210 of the module mounting panel 200 may be adjusted according to power requirements, and each of the bulb-type light concentrated solar cell module 100 may be readily replaced when the efficiency of the bulb-type light concentrated solar cell module 100 is reduced.

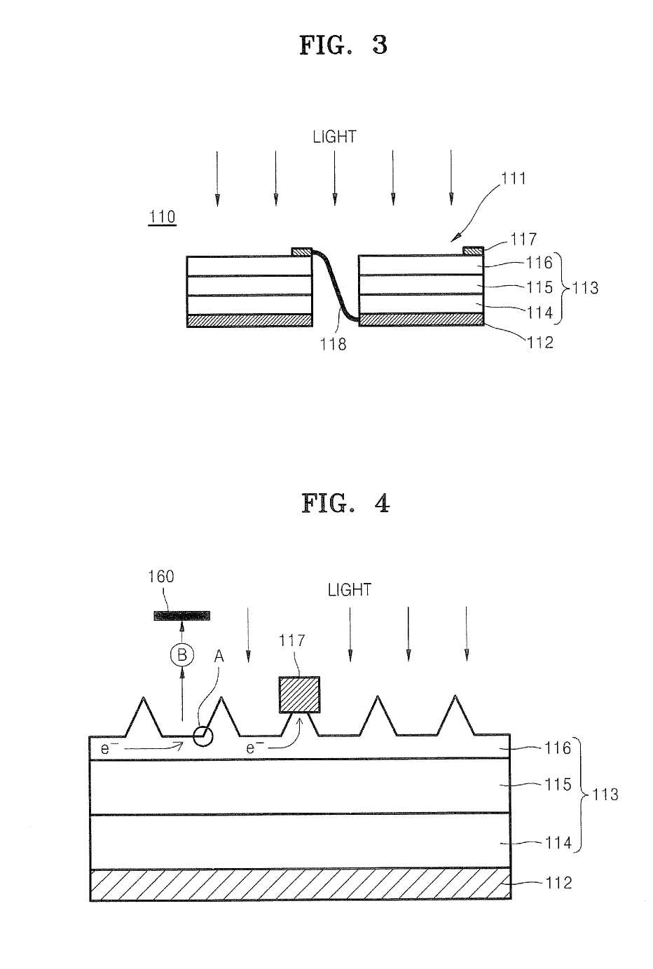

FIG. 3 is a cross-sectional view illustrating a unit cell 111 of the solar cell 110 of FIG. 1. Referring to FIG. 3, the solar cell 110 may comprise a plurality of unit cells 111. The unit cell 111 includes a first electrode 112, a second electrode 117, and a photovoltaic layer 113 that is formed between the first electrode 112 and the second electrode 117 and comprises a plurality of layers, for example, first through third layers 114, 115, and 116. The second electrode 117 is formed on a side where light enters, and the first electrode 112 is formed on an opposite side of the photovoltaic layer 113 to the second electrode 117. A wire 118 may be formed to connect two unit cells 111 in series.

The first electrode 112 and the second electrode 117 may be formed of a conventional electrode material such as Al. Also, the second electrode 117 may be formed of a transparent conductive material such as a transparent conductive oxide (TCO), for example indium tin oxide (ITO), so that sunlight can pass through.

The first layer 114 that contacts the first electrode 112, the third layer 116 that contacts the second electrode 117, and the second layer 115 between the first and the third layers may be formed of a semiconductor material. The third layer 116 has the largest band gap and the first layer 114 has the smallest band gap. The band gap of the second layer 115 lies between the band gaps of the first and the third layers 114 and 116. In this way, since the band gap gradually reduces from the third layer 116 towards the first layer 114, photoelectrons of sunlight, having energy greater than the band gap of the third layer 116 are used to generate electricity by using energy as much as the band gap of the third layer 116 and the remaining energy is converted into heat in the third layer 116. Photoelectrons having energy less than the band gap of the third layer 116 are converted into electricity and heat in the second layer 115. Also, photoelectrons having energy less than the band gap of the second layer 115 are converted into electricity and heat in the first layer 114, and photoelectrons having energy less than the band gap of the first layer 114 is converted into heat. The first through third layers 114, 115, and 116 may be respectively formed of Ge, GaAs, and GaInP, and each of Ge, GaAs, and GaInP has band gap energy of 0.7 eV, 1.4 eV, and 1.8 eV, respectively.

The photovoltaic layer 113 of the unit cell 111 may comprises more than four layers, and each of the layers may be formed of various materials.

The solar cell 110 according to the present invention is not limited to the multi-junction cell described above, and may be a cell formed of silicon material.

The solar cell 110 includes a plurality of the unit cells 111 connected in series. The first electrode 112 formed on an end of the unit cell 111 of the solar cell 110 is connected to the p-type terminal 142 of the power control unit 140, and the second electrode 117 formed on the other end of the unit cell 111 of the solar cell 110 is connected to the n-type terminal 141 of the power control unit 140.

FIG. 4 is a schematic drawing for explaining the movement of electrons at a surface of the unit cell 111 of the solar cell 110 of FIG. 1. Referring to FIG. 4, the surface of the third layer 116 through which light enters has a pyramid shape in order to absorb a large amount of light. Of the electrons formed in the photovoltaic layer 113, the electrons formed close to the second electrode 117 are readily moved to the second electrode 117. However, electrons formed further away from the second electrode 117 may be lost at, for example, a corner A of the surface of the third layer 116 in the course of moving towards the second electrode 117 due to recombining with holes, and thus, the generation efficiency of the bulb-type light concentrated solar cell module 100 may be reduced.

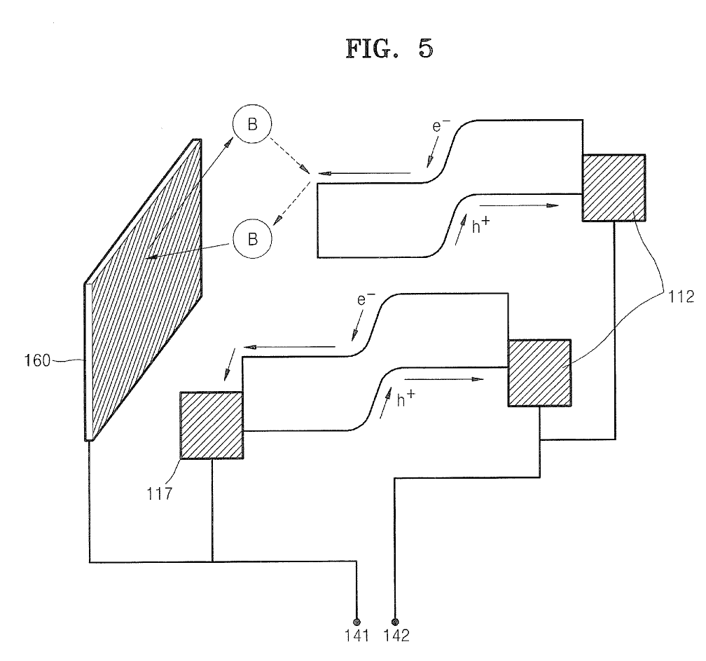

However, to prevent this, a fifth electrode 160 is further installed around and laterally adjacent to the third layer 116 in the unit cell 111 of the solar cell 110 according to an embodiment of the present invention. A first gas having an electron affinity higher than that of the third layer 116 is filled in the sealed space 152. The function of the fifth electrode 160 is described below with respect to FIGS. 4 and 5.

The fifth electrode 160 is formed of a material having an electron affinity higher than that of the first gas. The first gas may be F₂, Cl₂, or I₂. The fifth electrode 160 may be formed of Pt, Pd, or TaN.

FIG. 5 is a schematic drawing for explaining the operation of the solar cell 110 according to an embodiment of the present invention.

Referring to FIGS. 4 and 5, when light is irradiated onto the unit cell 111, electron-hole pairs are formed in the photovoltaic layer 113, and thus, the electrons are moved to the second electrode 117 and the holes are moved to the p-type terminal 142 of the power control unit 140 through the first electrode 112. Meanwhile, electrons formed in the photovoltaic layer 113 far away from the second electrode 117 are moved to the surface of the third layer 116. The first gas B present on the surface of the third layer 116 absorbs electrons since the first gas B has an electron affinity higher than that of the third layer 116, and thus, the recombining of the electrons with holes at a corner A of the surface of the third layer 116 is prevented. Also, electrons escaping from the surface of the third layer 116 and adsorbed by the first gas B move to the fifth electrode 160 having a high electron affinity. The electrons moved to the fifth electrode 160 move to the n-type terminal 141 of the power control unit 140 via a wire connected to the fifth electrode 160. Thus, the electrons moved to the second electrode 117 and the fifth electrode 160 move together to the n-type terminal 141.

In FIG. 5, the first electrode is separated into two parts in order to show the respective band energy diagram. However, in practice, the first electrode 112 may be formed as a single electrode.

Thus, the bulb-type light concentrated solar cell module 100 according to an embodiment of the present invention prevents recombining of electrons with holes at the surface of the solar cell 110, and thus, increases the power efficiency of the unit cells 111.

Meanwhile, when a fluorine group molecule such as CoF₄ or tetrafluorotetracyanoquinodimethane (F4-TCNQ) instead of the first gas B is formed on the surface of the unit cell 111, particularly on the surface of the third layer 116 and the sealed space 152 is maintained at a vacuum or filled with an inert gas, the above gas effect may also be obtained. However, further description thereof will be omitted.

Also, when a semiconductor oxide is used as the solar cell 110, the first gas B may be O₂.

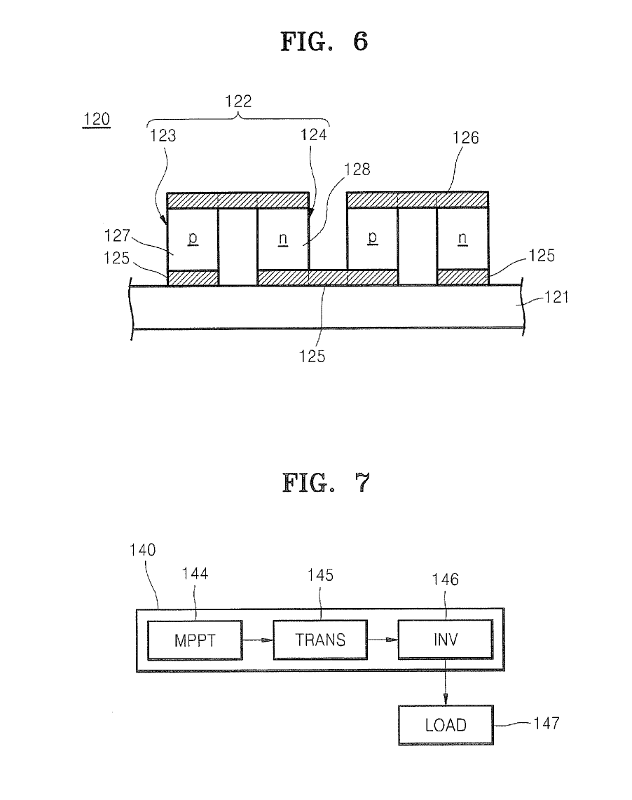

FIG. 6 is a cross-sectional view of a modified version of the structure of the reflective mirror unit 120 of FIG. 1.

Referring to FIG. 6, the reflective mirror unit 120 includes a concave substrate 121 and a plurality of thermoelectric cells 122 disposed on the substrate 121. Each of the thermoelectric cells 122 includes a p-type stack 123 and an n-type stack 124 formed on the substrate 121. Each of the stacks 123 and 124 includes a third electrode 125 on the substrate 121, thermoelectric material film 127 or 128 on the third electrode 125, and a fourth electrode 126 on the thermoelectric material film 127 or 128. The p-type thermoelectric material film 127 is formed in the p-type stack 123, and the n-type thermoelectric material film 128 is formed in the n-type stack 124, and thus, the thermoelectric cells 122 have a P-N structure. The substrate 121 may be formed of glass or transparent plastic.

The fourth electrode 126 of both of the stacks 127 and 128 of each thermoelectric cell 122 may be formed as a single second electrode 126 by being connected to both stacks 127 and 128, and the third electrode 125 of the n-type stack 128 of a thermoelectric cell 122 and the third electrode 125 of the p-type stack 127 of an adjacent thermoelectric cell 122 may be formed as a single third electrode 125.

The third electrode 125 under the p-type stack 123 of first thermoelectric cell 122 and the third electrode 125 of the n-type stack 124 of the last thermoelectric cells 122 are connected to the p-type terminal 142 and the n-type terminal 142 of the power control unit 140, respectively.

The n-type thermoelectric material film 128 may be formed at least one of Bi₂(Te,Se)₃, Nb-doped SrTiO₃, CaMn_{0.98}Mo_{0.02}O₃, and (Bi₂Te₃)_{0.9}(Sb₂Te₃)_{0.05}(Sb₂Se₃)_{0.05}, and the p-type thermoelectric material film 127 may be formed of at least one material selected from the group consisting of (Bi,Sb)₂Te₃, Ca₃Co₄O₉, and (Bi₂Te₃)_{0.2}(Sb₂Te₃)_{0.8-y}(Sb₂Se₃)_{y} (0≦y≦0.07).

As the fourth electrodes 126 follow the general shape of the reflective mirror unit 120 they are also formed in a concave shape like the substrate 121 to form a reflection surface of the reflective mirror unit 120.

When the thermoelectric cells 122 receive light, electrons are generated in the n-type thermoelectric material film 128 and the electrons are moved to the third electrode 125, and holes are generated in the p-type thermoelectric material film 127 and the holes are moved to the third electrode 125. The thermoelectric cells 122 supply a few tens or hundreds of direct current voltage to the power control unit 140 according to the number of cells.

The p-type thermoelectric material film 127 and the n-type thermoelectric material film 128 respectively may be formed in a nanowire shape.

FIG. 7 is a block diagram showing an example of the power control unit 140 of FIG. 1.

Referring to FIG. 7, the power control unit 140 includes a maximum power tracking circuit 144, a booster 145, and an inverter 146.

The maximum power tracking circuit 144 receives a direct current from the solar cell 110 and the thermoelectric cells 122. The maximum power point tracking circuit 144 outputs a maximum voltage by controlling the inputted current.

The booster 145 boosts the direct current voltage outputted from the maximum power tracking circuit 144 to a predetermined direct current voltage. This is to increase the conversion efficiency of a direct current to an alternating current in the inverter 146.

The inverter 146 converts the direct current inputted from the booster 145 to an alternating current and supplies electricity to a load 147 or a condenser battery (not shown) connected to the inverter 146.

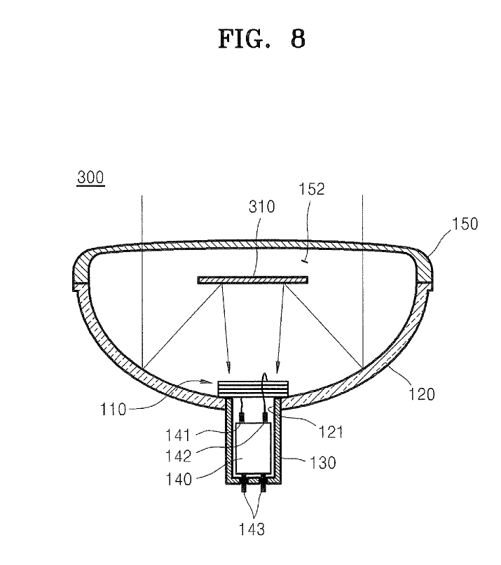

FIG. 8 is a cross-sectional view of a bulb-type light concentrated solar cell module according to another embodiment of the present invention. Like reference numerals are used to indicate substantially identical elements of FIG. 1, and thus, their description will not be repeated.

Referring to FIG. 8, a solar cell 110 of a bulb-type light concentrated solar cell module 300 is positioned on the first hole 121, and a second reflective mirror 310 is disposed above the solar cell 110. The second reflective mirror 310 is concavely formed towards the solar cell 110 to increase concentration efficiency of sunlight irradiated onto the small sized solar cell 110. Meanwhile, the third layer 116 of the solar cell 110 is disposed to face the second reflective mirror 310.

While the present invention has been particularly shown and described with reference to exemplary embodiments thereof it will be understood by one of ordinary skill in the art that various changes in form and details may be made therein without departing from the spirit and scope of the present invention as defined by the following claims.

1. A bulb-type light concentrated solar cell module comprising:
a reflective mirror unit that is concavely formed to convergingly reflect sunlight and has a first hole on a bottom thereof;
a solar cell that generates electrical energy in response to light received from the reflective mirror unit;
a socket that blocks the first hole at a lower part of the reflective mirror unit and is fixed on the reflective mirror unit; and
a power control unit that is electrically connected to the solar cell to generate electricity in the socket.

2. The bulb-type light concentrated solar cell module of claim 1, wherein the solar cell is disposed above the first hole for light reflected by the reflective mirror unit to be incident thereon.

3. The bulb-type light concentrated solar cell module of claim 1, wherein the solar cell is positioned on the first hole, and further comprises a second reflective mirror disposed above the first hole to reflect light incident thereon from the reflective mirror unit onto the solar cell.

4. The bulb-type light concentrated solar cell module of claim 1, wherein the reflective mirror unit comprises:
a concave substrate; and
a thermoelectric cell formed on the substrate,
wherein the thermoelectric cell comprises a p-type stack and an n-type stack,
the p-type stack comprises a first electrode on the substrate, a p-type thermoelectric material film on the first electrode, and a second electrode on the p-type thermoelectric material film, and
the n-type stack comprises a first electrode on the substrate, an n-type thermoelectric material film on the first electrode, and a second electrode on the n-type thermoelectric material film.

5. The bulb-type light concentrated solar cell module of claim 4, wherein the first electrode of the p-type stack and the first electrode of the n-type stack are respectively connected to a p-type terminal and an n-type terminal of the power control unit.

6. The bulb-type light concentrated solar cell module of claim 4, wherein the thermoelectric cell comprises a plurality of thermoelectrical cell connected in series, and the first electrode of the p-type stack of the first thermoelectric cell and the first electrode of the n-type stack of the last thermoelectric cell are respectively connected to a p-type terminal and an n-type terminal of the power control unit.

7. The bulb-type light concentrated solar cell module of claim 4, wherein the p-type thermoelectric, material film is formed of at least one selected from the group consisting of (Bi,Sb)₂Te₃, Ca₃Co₄O₉, and (Bi₂Te₃)_{0.2}(Sb₂Te₃)_{0.8-y}(Sb₂Se₃)_{y} (0≦y≦0.07), and the n-type thermoelectric material film is formed of at least one selected from the group consisting of Bi₂(Te,Se)₃, Nb-doped SrTiO₃, and CaMn_{0.98}Mo_{0.02}O₃, (Bi₂Te₃)_{0.9}(Sb₂Te₃)_{0.05}(Sb₂Se₃)_{0.05}.

8. The bulb-type light concentrated solar cell module of claim 5, wherein the p-type thermoelectric material film and the n-type thermoelectric material film are each a nanowire.

9. The bulb-type light concentrated solar cell module of claim 1, further comprising a transparent cover formed on the reflective mirror unit to form a sealed space with the reflective mirror unit, and a first gas filled in the sealed space,
wherein the solar cell comprises a plurality of unit cells each having a third electrode formed towards the reflective mirror unit and a fourth electrode opposite to the third electrode, a fifth electrode formed laterally adjacent to the third electrode and separate from the third electrode,
and the first gas having an electron affinity higher than that of the third electrode, and the fifth electrode is formed of a metal having an electron affinity higher than that of the first gas.

10. The bulb-type light concentrated solar cell module of claim 9, wherein the third electrode and the fifth electrode are connected together to an n-type terminal of the power control unit, and the fourth electrode is connected to a p-type terminal of the power control unit.

11. The bulb-type light concentrated solar cell module of claim 9, wherein the first gas is at least one selected from the group consisting F₂, Cl₂, and I₂.

12. The bulb-type light concentrated solar cell module of claim 9, wherein the fifth electrode is formed of a metal selected from the group consisting of Pt, Pd, and TaN.

13. The bulb-type light concentrated solar cell module of claim 9, wherein the reflective mirror unit comprises:
a concave substrate; and
a thermoelectric cell formed on the substrate,
wherein the thermoelectric cell comprises a p-type stack and an n-type stack,
the p-type stack comprises a first electrode on the substrate, a p-type thermoelectric material film on the first electrode, and a second electrode on the p-type thermoelectric material film, and
the n-type stack comprises a first electrode on the substrate, an n-type thermoelectric material film on the first electrode, and a second electrode on the n-type thermoelectric material film

14. The bulb-type light concentrated solar cell module of claim 1, further comprising a transparent cover formed on the reflective mirror unit to form a sealed space with the reflective mirror unit, and,
the solar cell comprises a plurality of unit cells each having a third electrode formed towards the reflective mirror unit and a fourth electrode opposite to the third electrode, and a fluorine group molecule of CoF₄ or tetrafluorotetracyanoquinodimethane (F4-TCNQ) adsorbed on a surface of the third electrode, a fifth electrode formed laterally adjacent to the third electrode and separate from the third electrode, wherein the fifth electrode is formed of a metal having an electron affinity higher than that of the fluorine group molecule of CoF₄ or F4-TCNQ.

15. The bulb-type light concentrated solar cell module of claim 14, wherein the third electrode and the fifth electrode are connected together to an n-type terminal of the power control unit, and the fourth electrode is connected to a p-type terminal of the power control unit.

16. The bulb-type light concentrated solar cell module of claim 14, wherein the fifth electrode is formed of a metal selected from the group consisting of Pt, Pd, and TaN.

17. The bulb-type light concentrated solar cell module of claim 14, wherein the reflective mirror unit comprises:
a concave substrate; and
a thermoelectric cell formed on the substrate,
wherein the thermoelectric cell comprises a p-type stack and an n-type stack,
the p-type stack comprises a first electrode on the substrate, a p-type thermoelectric material film on the first electrode, and a second electrode on the p-type thermoelectric material film, and
the n-type stack comprises a first electrode on the substrate, an n-type thermoelectric material film on the first electrode, and a second electrode on the n-type thermoelectric material film

18-36. (canceled)
